(19) United States
(12) Patent Application Publication
(10) Pub. No.: US 2023/0278315 A1
(43) Pub. Date: Sep. 7, 2023

(54) COMPOSITE SUBSTRATE AND MANUFACTURING METHOD THEREOF

(71) Applicant: Hong Chuang Applied Technology Co., Ltd., Zhubei City (TW)

(72) Inventors: YAN-KAI ZENG, Zhubei City (TW); BAI-XUAN JIANG, Zhubei City (TW); RUI-FENG JIANG, Zhubei City (TW)

(21) Appl. No.: 17/845,874

(22) Filed: Jun. 21, 2022

(30) Foreign Application Priority Data
Mar. 1, 2022 (TW) 111107364

(51) Int. Cl. B32B 9/00; B32B 37/18; B32B 38/10

(52) U.S. Cl. CPC B32B 9/005; B32B 37/18; B32B 38/10; H01L 23/14

(57) ABSTRACT

A composite substrate and a manufacturing method thereof are provided. By disposing a plurality of interlayers between a carrier plate and a substrate, a strong bonding force between the layers can be ensured, and the difference between the coefficients of thermal expansion of the layers is allowed to be adjusted to prevent such drawbacks as the substrate being likely to break.

### BACKGROUND OF THE INVENTION

### 1. Technical Field

The present invention relates mainly to, but is not limited to, a composite substrate and a method for making the same.

### 2. Description of Related Art

Power devices are important components for the transmission and conversion of electrical energy and can be used in a great variety of areas, from low-power consumer electronics to high-power transportation-related applications, green energy-related applications, industrial motors, and so on. While power devices are nowadays typically made of crystalline silicon substrates, the use of wide-bandgap compound semiconductors (e.g., silicon carbide, gallium(III) trioxide, and gallium nitride) in power devices has also attracted much attention.

In practice, however, a composite substrate structure composed of multiple materials may be preferred given such factors in substrate material selection as the physical/chemical properties of materials and the manufacturing cost, the objective being to provide the end product with a competitive edge in every aspect.

### BRIEF SUMMARY OF THE INVENTION

This part of the specification aims to provide a brief summary of the invention so as to enable a basic understanding of the invention. The brief summary of the invention is neither a complete description of the invention nor intended to point out the important or key elements of certain embodiments of the invention or define the scope of the invention.

Continued from the Description of Related Art, the inventor of the present invention has found that a composite material whose different layers are made of the same material may have weak van der Waals bonds, and that a composite material whose different layers are made of different materials respectively may break because of a difference in the coefficient of expansion.

In view of the above, one aspect of the present invention provides a composite substrate that includes a substrate, a carrier plate, and a plurality of interlayers. The carrier plate is so disposed that it corresponds to the substrate. The interlayers are disposed between the substrate and the carrier plate.

In one embodiment of the present invention, the substrate is a polycrystalline or monocrystalline material whose constituent is nitride ceramic, oxide ceramic, carbide ceramic, silicon, silicon carbide, gallium nitride, sapphire (aluminum oxide), gallium arsenide, or gallium(III) trioxide.

In one embodiment of the present invention, the carrier plate is a polycrystalline or monocrystalline material whose constituent is nitride ceramic, oxide ceramic, carbide ceramic, silicon, silicon carbide, gallium nitride, sapphire (aluminum oxide), gallium arsenide, or gallium(III) trioxide.

In one embodiment of the present invention, each interlayer is a polycrystalline or monocrystalline material whose constituent is a nitride, an oxide, an oxynitride, or a carbide.

In one embodiment of the present invention, the interlayers include at least one first interlayer and at least one second interlayer alternately stacked together, and the first interlayer and the second interlayer have different constituents respectively or have the same constituent in different crystalline forms.

Another aspect of the present invention provides a manufacturing method of a composite substrate, wherein the manufacturing method is carried out as follows. First, a substrate and a carrier plate are provided. The carrier plate is disposed in such a way that it corresponds to and is parallel to the substrate, with a plurality of interlayers disposed between the substrate and the carrier plate. After that, the carrier plate is made to form a film.

In one embodiment of the present invention, the substrate and the carrier plate have different constituents respectively or have the same constituent in different crystalline forms.

In one embodiment of the present invention, the interlayers include at least one first interlayer and at least one second interlayer alternately stacked together, and the first interlayer and the second interlayer have different constituents respectively or have the same constituent in different crystalline forms.

In one embodiment of the present invention, the film has a thickness ranging from 0.5 nm to 1000 μm.

Yet another aspect of the present invention provides a manufacturing method of a composite substrate, wherein the manufacturing method is carried out as follows. A substrate and a carrier plate are provided. At least one interlayer is formed on the substrate, and a film and at least one interlayer are sequentially formed on the carrier plate. The substrate and the carrier plate are bonded together through the interlayers, and then the carrier plate is removed, thinned, or cut.

In one embodiment of the present invention, the substrate and the carrier plate have different constituents respectively or have the same constituent in different crystalline forms.

The present invention is advantageous in that by disposing the plurality of interlayers between the carrier plate and the substrate, not only is a strong bonding force ensured between the layers of the composite substrate provided by the invention, but also the difference, if any, between the coefficients of thermal expansion of the layers is allowed to be regulated to prevent such drawbacks as the substrate being likely to break.

### BRIEF DESCRIPTION OF THE SEVERAL VIEWS OF THE DRAWINGS

The foregoing and other objectives, features, and advantages of the present invention can be better understood by referring to the following detailed description of some illustrative embodiments in conjunction with the accompanying drawings, in which:

FIG. 1 schematically shows the layered structure of a composite substrate; and

FIG. 2 to FIG. 4 schematically show the layered structures according to different embodiments of the invention.

As is conventional, the various features and elements in the drawings are not necessarily drawn to scale; the drawings are provided to show the features and elements related to the present invention in an ideal manner. In addition, identical or similar reference numerals in the drawings refer to similar elements or parts.

### DETAILED DESCRIPTION OF THE INVENTION

To describe the present invention more thoroughly, certain modes of implementation and embodiments of the invention are detailed below. Those modes of implementation and embodiments, however, are not the only forms in which the invention can be implemented. In this specification and the appended claims, “a/an” and “the/said” may be interpreted as referring to plural referents unless otherwise stated in the context. Also, the phrase “disposed on something” in the specification and the appended claims may be interpreted as in direct or indirect contact with a surface of that thing by an attaching or other means unless otherwise stated, wherein the definition of the surface depends on the context and can be determined according to the common knowledge of a person of ordinary skill in the art.

While all the numerical ranges and parameters used to define the present invention are approximate values, the related values in the embodiments have been presented herein as precisely as possible. It should be understood, however, that it is essentially unavoidable for a value to show a standard deviation resulting from an individual testing method. Herein, the word “about” or “approximately” preceding a specific value or numerical range indicates that the actual value or numerical range is within ±10%, ±5%, ±1%, or ±0.5% of that specific value or numerical range. Or, the word “about” or “approximately” indicates that the actual value falls within an acceptable standard deviation of an average value, as can be determined by a person of ordinary skill in the art. Therefore, unless stated otherwise, all the numerical parameters disclosed in this specification and the appended claims are approximate values and may be changed as required. Such a numerical parameter should at least be construed as a value having the specified significant digits and obtained by a common carry method.

The present invention provides a composite substrate that includes a substrate, a carrier plate, and a plurality of interlayers. The carrier plate is so disposed that it corresponds to the substrate. The interlayers are disposed between the substrate and the carrier plate.

The “substrate” referred to herein is a polycrystalline or monocrystalline material, whose constituent can be classified as ceramic or a semiconductor material. “Ceramic” refers to an inorganic non-metal solid material obtained by performing a high-temperature treatment on a compound of a metal and a non-metal; includes a silicate, an oxide, a carbide, a nitride, a sulfide, a boride, and so on; and is preferably, but not necessarily, selected from the group consisting of aluminum nitride, aluminum oxide, silicon carbide, and silicon nitride. More specifically, the constituent of the substrate is selected from the group consisting of nitride ceramic, oxide ceramic, carbide ceramic, silicon, silicon carbide, sapphire (aluminum oxide), gallium nitride, gallium arsenide, and gallium(III) trioxide.

The “carrier plate” referred to herein is also a polycrystalline or monocrystalline material, whose constituent can be classified as ceramic or a semiconductor material. “Ceramic” refers to an inorganic non-metal solid material obtained by performing a high-temperature treatment on a compound of a metal and a non-metal; includes a silicate, an oxide, a carbide, a nitride, a sulfide, a boride, and so on; and is preferably, but not necessarily, selected from the group consisting of aluminum nitride, aluminum oxide, silicon carbide, and silicon nitride. More specifically, the constituent of the carrier plate is selected from the group consisting of nitride ceramic, oxide ceramic, carbide ceramic, silicon, silicon carbide, sapphire (aluminum oxide), gallium nitride, gallium arsenide, and gallium(III) trioxide.

The substrate and the carrier plate are made of the same material or are made of different materials respectively. In some embodiments of the present invention, the substrate and the carrier plate are made of different materials respectively in order for the composite substrate of the invention to have a strong bonding force.

The “interlayer” referred to herein is a polycrystalline or monocrystalline material whose constituent is an oxide, a nitride, a carbide, or an oxynitride. More specifically, the constituent of each interlayer is selected from the group consisting of aluminum oxide, silicon oxide, gallium(III) trioxide, titanium oxide, aluminum nitride, silicon nitride, gallium nitride, silicon carbide, aluminum oxynitride, silicon oxynitride, and gallium oxynitride.

In some embodiments of the present invention, the interlayers include at least one first interlayer and at least one second interlayer alternately stacked together, and the first interlayer and the second interlayer have different constituents respectively or have the same constituent in different crystalline forms.

### Manufacturing Method

The present invention provides a manufacturing method of a composite substrate, wherein the manufacturing method includes the steps of: providing a substrate and a carrier plate; disposing the carrier plate in such a way that it corresponds to and is parallel to the substrate, and disposing a plurality of interlayers between the substrate and the carrier plate; and making the carrier plate form a film. In one preferred embodiment of the invention, the constituent of the substrate is different from that of the carrier plate. In one preferred embodiment of the invention, the interlayers include at least one first interlayer and at least one second interlayer alternately stacked together, and the first interlayer and the second interlayer have different constituents respectively or have the same constituent in different crystalline forms.

A different embodiment of the present invention provides another manufacturing method of a composite substrate, wherein the manufacturing method includes the steps of: providing a substrate and a carrier plate; forming at least one interlayer on the substrate, and sequentially forming a film and at least one interlayer on the carrier plate; bonding the substrate and the carrier plate together through the interlayers; and removing, thinning, or cutting the carrier plate. Depending on user needs, the step of removing, thinning, or cutting the carrier plate may alternatively involve making the carrier plate form a film. In one preferred embodiment of the invention, the constituent of the carrier plate is different from that of the substrate.

Both the substrate and the carrier plate have a thickness ranging from 100 to 1500 pm, such as 100, 200, 300, 400, 500, 600, 700, 800, 900, 1000, 1100, 1200, 1300, 1400, or 1500 μm. Each interlayer has a thickness approximately ranging from 10 to 200 nm, such as 10, 50, 100, 150, or 200 nm. The “film” referred to herein is a film having a thickness ranging from 0.5 nm to 1000 μm, such as but not limited to 0.5 nm, 100 nm, 100 μm, or 1000 μm.

In terms of the manufacturing process, operations required for manufacturing the substrate layers such as “disposing” and “forming” can be performed by any applicable method in the art, including but not limited to chemical vapor deposition (CVD), low-pressure CVD (LPCVD), atmospheric-pressure CVD (APCVD), ultrahigh-vacuum CVD (UHVCVD), atomic layer deposition (ALD), molecular layer deposition (MLD), plasma-enhanced CVD (PECVD), metal-organic CVD (MOCVD), molecular beam epitaxy (MBE), sputtering, or a combination of the above.

### Embodiments

Certain embodiments of the present invention and a comparative example are described below with reference to the accompanying drawings. The embodiments and the comparative example serve only to expound the contents of the invention but not to limit the scope of the invention.

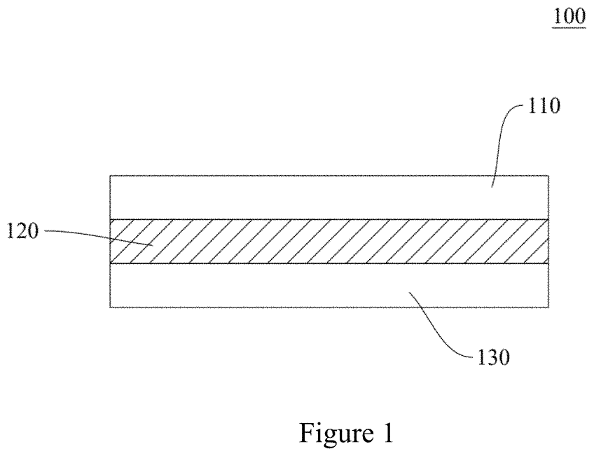

FIG. 1 schematically shows the layered structure of a composite substrate 100. As shown in FIG. 1, the composite substrate 100 includes a carrier plate 110 and a substrate 130. The substrate 130 is so disposed as to correspond to the carrier plate 110. A single interlayer 120 is disposed between the substrate 130 and the carrier plate 110. More specifically, the material of the carrier plate 110 is silicon carbide, the material of the substrate 130 is aluminum nitride, and the material of the interlayer 120 is aluminum oxide.

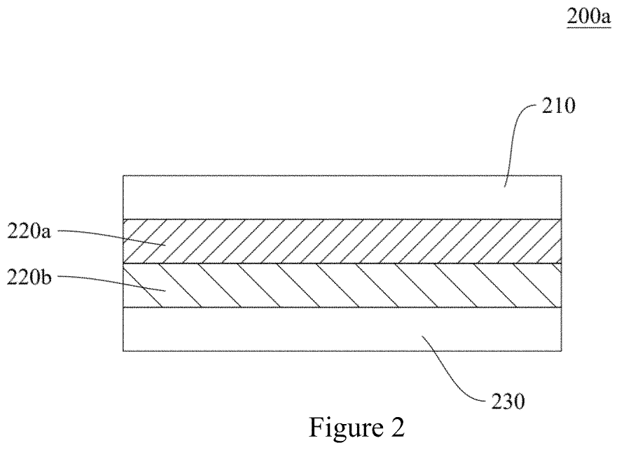

FIG. 2 schematically shows the layered structure of the composite substrate 200a according to an embodiment of the present invention. As shown in FIG. 2, the composite substrate 200a includes a carrier plate 210 and a substrate 230. The substrate 230 is so disposed as to correspond to the carrier plate 210. A plurality of interlayers, namely a first interlayer 220a and a second interlayer 220b, are disposed between the substrate 230 and the carrier plate 210. More specifically, the material of the carrier plate 210 is silicon carbide, the material of the substrate 230 is aluminum nitride, and the material of each of the first interlayer 220a and the second interlayer 220b is silicon oxide or aluminum oxide. The first interlayer 220a and the second interlayer 220b may be made of the same material, or made of different materials respectively, or made of materials having the same constituent in different crystalline forms respectively. In this embodiment, the material of the first interlay 220a is silicon oxide, and the material of the second interlay 220b is aluminum oxide.

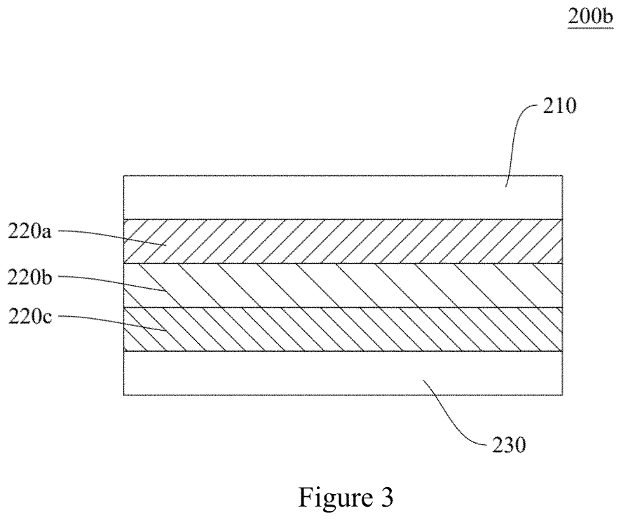

FIG. 3 schematically shows the layered structure of the composite substrate 200b according to an embodiment of the present invention. As shown in FIG. 3, the composite substrate 200b includes a carrier plate 210 and a substrate 230. The substrate 230 is so disposed as to correspond to the carrier plate 210. A plurality of interlayers, namely a first interlayer 220a, a second interlayer 220b, and a third interlayer 220c, are disposed between the substrate 230 and the carrier plate 210. More specifically, the material of the carrier plate 210 is silicon carbide, the material of the substrate 230 is aluminum nitride, and each of the first interlayer 220a, the second interlayer 220b, and the third interlayer 220c is silicon oxide or aluminum oxide. The first interlayer 220a, the second interlayer 220b, and the third interlayer 220c may be made of the same material, or made of materials having the same constituent in different crystalline forms respectively, or made of different materials respectively, or provided by stacking two different materials in an alternate manner. In this embodiment, the material of the first interlayer 220a is silicon oxide, the material of the second interlayer 220b is aluminum oxide, and the material of the third interlayer 220c is silicon oxide.

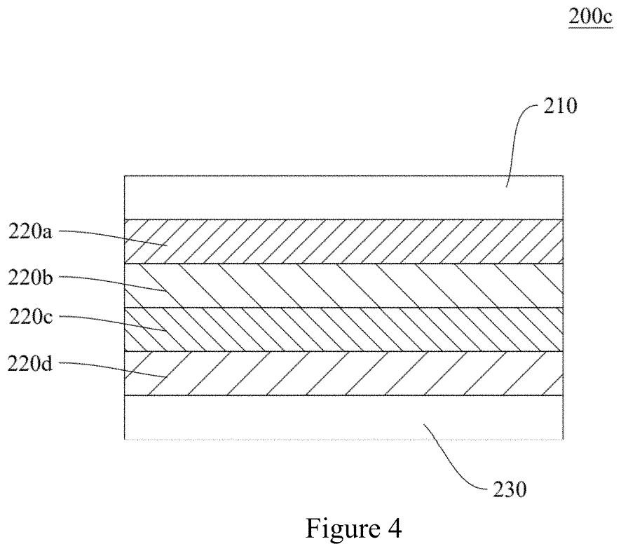

FIG. 4 schematically shows the layered structure of the composite substrate 200c according to an embodiment of the present invention. As shown in FIG. 4, the composite substrate 200c includes a carrier plate 210 and a substrate 230. The substrate 230 is so disposed as to correspond to the carrier plate 210. A plurality of interlayers, namely a first interlayer 220a, a second interlayer 220b, a third interlayer 220c, and a fourth interlayer 220d, are disposed between the substrate 230 and the carrier plate 210. More specifically, the material of the carrier plate 210 is silicon carbide, the material of the substrate 230 is aluminum nitride, and each of the first interlayer 220a, the second interlayer 220b, the third interlayer 220c, and the fourth interlayer 220d is silicon oxide or aluminum oxide. The four interlayers may be made of the same material, or made of different materials respectively, or provided by stacking two different materials in an alternate manner. In this embodiment, the material of the first interlayer 220a is silicon oxide, the material of the second interlayer 220b is aluminum oxide, the material of the third interlayer 220c is silicon oxide, and the material of the fourth interlayer 220d is aluminum oxide.

### Determination of Tensile Strength

The tensile strength of the composite substrates 100, 200a, 200b, and 200c were tested. The testing procedure included soldering the carrier plate or the substrate of a composite substrate under test to at least one pulling cord, and pulling the pulling cord with a stretching machine so as to determine the tensile strength of the composite substrate under test.

The test results are as follows. A sample of the composite substrate 100 had a tensile strength of about 5 kgf/cm₂, a sample of the composite substrate 200a had a tensile strength of about 7 kgf/cm₂, a sample of the composite substrate 200b had a tensile strength of about 8 kgf/cm₂, and a sample of the composite substrate 200c had a tensile strength of about 8.3 kgf/cm₂.

As can be known from the test results of the composite substrates according to the foregoing embodiments of the present invention, disposing a plurality of interlayers between the carrier plate and the substrate of a composite substrate provided by the invention not only ensures a strong bonding force between the layers of the composite substrate, but also allows the difference, if any, between the coefficients of thermal expansion of the layers to be regulated, thereby enhancing the tensile strength of the composite substrate and preventing such drawbacks as the substrate being likely to break. This is especially true when the carrier plate and the substrate are made of different materials respectively and when the plural interlayers are provided by stacking different materials in an alternate manner.

While a detailed description of the present invention has been given above, it should be understood that the foregoing embodiments are only some preferred ones of the invention and are not intended to be restrictive of the scope of the invention. Any equivalent change or modification that is based on the appended claims shall fall within the scope of the invention.

What is claimed is:

1. A composite substrate, comprising:
a substrate;
a carrier plate disposed to correspond to the substrate; and
a plurality of interlayers disposed between the substrate and the carrier plate.

2. The composite substrate of claim 1, wherein the substrate is a polycrystalline or monocrystalline material having a constituent selected from the group consisting of nitride ceramic, oxide ceramic, carbide ceramic, silicon, silicon carbide, sapphire (aluminum oxide), gallium nitride, gallium arsenide, and gallium(III) trioxide.

3. The composite substrate of claim 1, wherein the carrier plate is a polycrystalline or monocrystalline material having a constituent selected from the group consisting of nitride ceramic, oxide ceramic, carbide ceramic, silicon, silicon carbide, sapphire (aluminum oxide), gallium arsenide, gallium nitride, and gallium(III) trioxide.

4. The composite substrate of claim 1, wherein each said interlayer is a polycrystalline or monocrystalline material having a constituent selected from the group consisting of a nitride, an oxide, an oxynitride, and a carbide.

5. The composite substrate of claim 4, wherein the interlayers comprise at least one first interlayer and at least one second interlayer alternately stacked together, and the first interlayer and the second interlayer have different constituents respectively or have a same constituent in different crystalline forms.

6. A manufacturing method of a composite substrate, comprising the steps of:
providing a substrate and a carrier plate;
disposing the carrier plate in such a way that the carrier plate corresponds to and is parallel to the substrate, and disposing a plurality of interlayers between the substrate and the carrier plate; and
making the carrier plate form a film.

7. The manufacturing method of claim 6, wherein the substrate and the carrier plate have different constituents respectively or have a same constituent in different crystalline forms.

8. The manufacturing method of claim 6, wherein the interlayers comprise at least one first interlayer and at least one second interlayer alternately stacked together, and the first interlayer and the second interlayer have different constituents respectively or have a same constituent in different crystalline forms.

9. The manufacturing method of claim 6, wherein the film has a thickness ranging from 0.5 nm to 1000 μm.

10. A manufacturing method of a composite substrate, comprising the steps of:
providing a substrate and a carrier plate;
forming at least one interlayer on the substrate, and sequentially forming a film and at least one interlayer on the carrier plate;
bonding the substrate and the carrier plate together through the interlayers; and
removing, thinning, or cutting the carrier plate.

11. The manufacturing method of claim 10, wherein the substrate and the carrier plate have different constituents respectively or have a same constituent in different crystalline forms.
